(19) United States
(12) Patent Application Publication
(10) Pub. No.: US 2006/0289892 A1
(43) Pub. Date: Dec. 28, 2006

(54) Method for preparing light emitting diode device having heat dissipation rate enhancement

(76) Inventors: Jae Seung Lee, Daejeon (KR); Min Ho Choi, Pohang-si (KR); Bu Gon Shin, Daejeon (KR); Jong Hoon Kang, Seoul (KR); Min A. Yu, Daejeon (KR); Duk Sik Ha, Cheongju-si (KR); Dong Han Kho, Dalseo-gu (KR); Sang Ki Chun, Daejoen (KR); Suk Ky Chang, Daejeon (KR); Soo Min Park, Daejeon (KR)

Correspondence Address: MCKENNA LONG & ALDRIDGE LLP, 1900 K STREET, NW, WASHINGTON, DC, 20006, US

(21) Appl. No.: 11/474,972

(22) Filed: Jun. 27, 2006

(30) Foreign Application Priority Data
Jun. 27, 2005 (KR) 2005-55783
Sep. 22, 2005 (KR) 2005-88435
Sep. 27, 2005 (KR) 2005-89660

(51) Int. Cl. H01L 33/00

(52) U.S. Cl. 257/103

(57) ABSTRACT

A method for fabricating an LED having section grown on a sapphire substrate, a boded structure, and a unit chip separated from the bonded structure. The method includes (a) bonding the section grown on a first surface of the sapphire substrate to a first surface of a first substrate with a first binder; (b) bonding a second surface of the first substrate to a first surface of a second substrate with a second binder; (c) removing the second substrate from a bonded structure obtained as a result of step (b) after polishing a second surface of the sapphire substrate; (d) separating the bonded structure into unit chips after the second substrate has been removed; and (e) bonding the second surface of the polished sapphire substrate provided in each unit chip to a lead frame, and removing the first substrate. This method improves heat dissipation efficiency.

This application claims the benefit of the filing date of Korean Patent Application Nos. 10-2005-0055783, 10-2005-0088435, 10-2005-0089660 filed on Jun. 27, 2005, Sep. 22, 2005 and Sep. 27, 2005 in the Korean Intellectual Property Office, the disclosure of which is incorporated herein in its entirely by reference.

### TECHNICAL FIELD

The present invention relates to a method for fabricating a high-output top emission-type light emitting diode device with a significantly enhanced heat dissipation efficiency, and more particularly to a method for fabricating a top emission-type light emitting diode device, a bonded structure fabricated by the method, a unit chip separated from the bonded structure and a light emitting diode device including the unit chip, in which the thickness of a sapphire substrate is intentionally reduced in order to improve lowering of a heat dissipation efficiency due to the sapphire substrate having a poor thermal conductivity, and a light emitting diode device fabricated by such a fabricating method.

### BACKGROUND ART

In the late 1990's, blue and green light emitting diodes made of gallium nitride-based semiconductors have succeeded in commercialization and a vast market for them is now established. A white light emitting diode, which is also made of the gallium nitride-based semiconductors, has been successfully commercialized in recent years and is growing rapidly. Particularly, the white light emitting diode is expected to replace conventional glow and fluorescent lamps and thus research thereon is being vigorously pursued.

A sapphire substrate having a thickness of 430 μm is mainly used for growing a gallium nitride-based compound semiconductor for the manufacture of a light emitting diode. Sapphire substrates are electrically isolated, so that the anode and cathode of LEDs are formed on the front face of a wafer.

In general, a low-output GaN-based light emitting diode is manufactured in such a manner as shown in FIG. 1 that a sapphire substrate 10, on which a crystal structure is grown, is put on a lead frame 20 and then the two electrodes 11, 12 are connected to an upper portion of the sapphire substrate 10. At this time, in order to improve a heat dissipation efficiency, the sapphire substrate 10 is bonded onto the lead frame 4 after reducing its thickness to become approximately 80 μm. Thermal conductivity of sapphire substrates 10 is approximately 50W/m·K. Therefore, even if the thickness is reduced to be about 80 μm, it has a high thermal resistance. Thus, the top emission-type structure as shown in FIG. 1 is mainly used for the manufacture of low- or mid-output light emitting diode devices and is difficult to be applied to a high-output light emitting diode device.

In the early development period of a high-output gallium nitride-based light emitting diode with a chip size of 1×1 mm² or more, studies have been mainly focused on a flip chip bonding method as shown in FIG. 2 in order to more improve a heat dissipation characteristic.

In the flip-chip bonding method, a chip with an LEDs structure is bonded to a sub-mount 30, such as silicon wafer (150 W/m·K) having superior thermal conductivity or an AIN ceramic substrate (about 180 W/m·K), with its inner surface facing out. In such a flip chip structure, since heat is emitted through the sub-mount substrate 30, a heat dissipation efficiency is improved as compared with a case of heat dissipation through the sapphire substrate 10, but there is a problem in that its manufacturing process is far more complicated than that of a general top emission-type structure and a yield of the flip chip bonding process is low, which results in the high unit cost of production and the low mass production capability.

Due to the above-mentioned problems, major leading manufacturers have recently shows a tendency to abandon the mass production of the flip chip-type light emitting diode device and return to the mass production of the conventional high-output top emission-type light emitting diode. However, they are confronted by thermal problems such as shortening of a device's lifetime due to a low thermal conductivity of the sapphire substrate. Therefore, it is earnestly desired in the art to improve a heat dissipation efficiency of the high-output top emission-type light emitting diode which can be simply manufactured and is excellent in mass production capability.

In another point of view, a sapphire substrate, which is provided within the conventional top emission-type light emitting diode device, is processed as follows: That is, a sapphire substrate surface, on which a light emitting diode section is formed, is bonded onto a ceramic block having a larger size than that of the sapphire substrate by use of shift wax or the like. Since the shift wax is solid at a normal temperature, but is converted into liquid at a temperature of about 125° C., the sapphire substrate is bonded onto the ceramic block by melting the shift wax at about 125° C. using such a property of the shift wax and then the bonded structure consisting of the sapphire substrate and the ceramic block is cooled down to a normal temperature. Subsequently, the back side of the sapphire substrate firmly fixed to the ceramic block by the shift wax is subjected to lapping and polishing to thin the sapphire substrate to a thickness of about 80 μm, and then the ceramic block is heated to above a melting point of the shift wax to separate the sapphire substrate from the ceramic block. Through such processing, the sapphire substrate is polished from an initial thickness of about 430 μm to a final thickness of about 80 μm. However, if the sapphire substrate is further thinned for improving the heat dissipation, not only the sapphire substrate is seriously bent, but also breakage of the sapphire substrate may occur only by separating the sapphire substrate from the ceramic block. In other words, the thickness of the sapphire substrate, which can be realized by the current polishing technology, is limited to a thickness of about 80 μm.

### DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a sectional view showing a structure of a low- or mid-output and top emission-type GaN-based light emitting diode device;

FIG. 2 is a sectional view showing a structure of a high-output GaN-based flip chip light emitting diode device;

FIG. 3 is a schematic view showing a fabricating method of a top emission-type light emitting diode device in accordance with a preferred embodiment of the present invention.

FIG. 4 is a schematic view showing the procedure for fabricating a top emission-type light emitting diode device in accordance with one embodiment of the present invention.

### BRIEF DESCRIPTION OF THE INDICATIONS IN THE DRAWINGS

10: sapphire substrate

20: lead frame

30: sub mount

40: bonding metal for flip chip

11: negative electrode

12: positive electrode

### DISCLOSURE OF THE INVENTION

Based on recognizing the above-mentioned problem occurring when the sapphire substrate having been polished to have a desired thickness is separated from the bonded structure consisting of the sapphire substrate and the ceramic block, inventors of the present invention have solved this problem by using another substrate (first substrate) in addition to the ceramic block (second substrate) serving to fix the sapphire substrate while the sapphire substrate is being polished, in which the first substrate is interposed between the sapphire substrate and the second substrate so as to continuously fix the sapphire substrate when the unit chip is formed after the sapphire substrate has been polished, and then is separated from the sapphire substrate when the sapphire substrate is bonded to the lead frame. In this case, the thickness of the sapphire substrate can be remarkably reduced from 80 μm to a predetermined level, so that the heat dissipation rate can be significantly improved and the manufacturing process for the light emitting diode can be simplified while achieving mass production of the light emitting diodes.

Therefore, it is an object of the present invention to provide a method for fabricating a light emitting diode device, which can improve the heat dissipation efficiency through a new sapphire processing (polishing) technology, and a light emitting diode device fabricated by such a fabricating method.

Another object of the present invention is to provide a bonded structure for a light emitting diode and a unit chip obtained from the bonded structure, which can facilitate polishing of the sapphire substrate, fixing of the polished sapphire substrate, and forming of the unit chip.

In order to accomplish the above objects, the present invention provides a light emitting diode device having a light emitting diode section grown on a sapphire substrate and a method for fabricating the light emitting diode device, in which the method comprising the steps of: (a) bonding the light emitting diode section grown on a first surface of the sapphire substrate to a first surface of a first substrate by means of a first binder; (b) bonding a second surface of the first substrate to a first surface of a second substrate by means of a second binder; (c) removing the second substrate from a bonded structure obtained as a result of step (b) after polishing a second surface of the sapphire substrate; (d) separating the bonded structure into unit chips after the second substrate has been removed from the bonded structure; and (e) bonding the second surface of the polished sapphire substrate provided in each unit chip to a lead frame, and then removing the first substrate.

According to another aspect of the present invention, there are provided a bonded structure comprising: (a) a first substrate made from a material suitable for a breaking process; and (b) a sapphire substrate formed on a first surface thereof with a light emitting diode section, wherein a first surface of the first substrate is bonded to the light emitting diode section of the sapphire substrate by means of a binder.

According to still another aspect of the present invention, there are provided a bonded structure and a unit chip separated from the bonded structure, in which the bonded structure comprising: (a) a first substrate formed on at least one surface thereof with at least one recess aligned in a regular interval; and (b) a sapphire substrate formed on a first surface thereof with a light emitting diode section, wherein a first surface of the first substrate is bonded to the light emitting diode section of the sapphire substrate by means of a binder.

Hereinafter, the present invention will be described in more detail.

The present invention provides a first substrate in addition to a second substrate (ceramic block) serving to fix a sapphire substrate when the sapphire substrate is polished and being removed after the sapphire substrate has been polished. The first substrate is interposed between the sapphire substrate and the second substrate so as to continuously fix the sapphire substrate, which has been polished to have a desired thickness, until the unit chip is formed and the sapphire substrate is bonded to the lead frame.

That is, since the second substrate is attached to processing equipment for the sapphire substrate, such as lapping and polishing equipment, in accordance with the standard of the processing equipment without taking the material or thickness of the second substrate into consideration, the second substrate is attached to the polished sapphire substrate. Accordingly, the second substrate cannot be applied to the process of forming the unit chip. In contrast, the present invention is made based on the fact that a substrate for supporting the sapphire substrate is necessary in order to significantly reduce the thickness of the sapphire substrate. Therefore, the present invention provides the first substrate in addition to the second substrate serving to fix the sapphire substrate while the sapphire substrate is being polished, in which the first substrate continuously supports (fixes) the polished sapphire substrate and properties of the first substrate, such as the material, the thickness, and the like, can be adjusted suitable for forming the unit chip in a state in which the first substrate has been bonded to the polished sapphire substrate.

Accordingly, the light emitting diode device according to the present invention has following advantages.

1) The ceramic block (second substrate) used for polishing the conventional sapphire substrate must be removed from the sapphire substrate after it has been used in a thinning process for the sapphire substrate, in order to form the unit chip. In contrast, according to the present invention, the first substrate is additionally interposed between the ceramic block (second substrate) and the sapphire substrate, so that the sapphire substrate can be processed to have a desired thickness (for example, less than 80 μm) and the sapphire substrate can be prevented from being broken or warped even if the ceramic block is removed from the bonded structure of the sapphire substrate and the first substrate, because the first substrate can support the sapphire substrate.

2) In addition, since the first substrate continuously supports the polished sapphire substrate until the unit chip has been formed, the structural stability can be improved. Also, the unit chip can be easily formed because the scribing and/or breaking process can be performed in a state in which the first substrate has been bonded to the sapphire substrate.

3) Furthermore, since the first substrate is not separated from the sapphire substrate until the sapphire substrate processed to have the desired thickness is structurally stabilized by being bonded to the lead frame, the conventional problem such as warpage or breakage of the sapphire substrate does not occur when the sapphire substrate is separated from the ceramic block (second substrate). Thus, the sapphire substrate can be polished to a final thickness less than the conventional thickness limit of 80 μm, preferably less than 40 μm, so the heat dissipation efficiency can be enhanced by at least twice as much as that of the conventional top emission-type light emitting diode device.

The light emitting diode device according to the present invention can be fabricated through various manners. For instance, a sapphire substrate, on which a light emitting diode crystal structure has been grown, is put on a lead frame and then two electrodes 11 and 12 are formed and connected to an external power source.

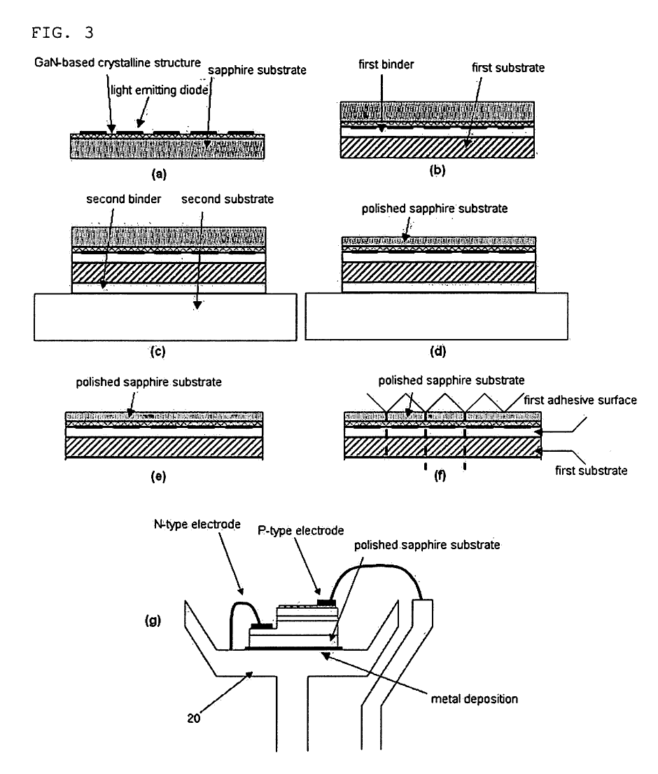

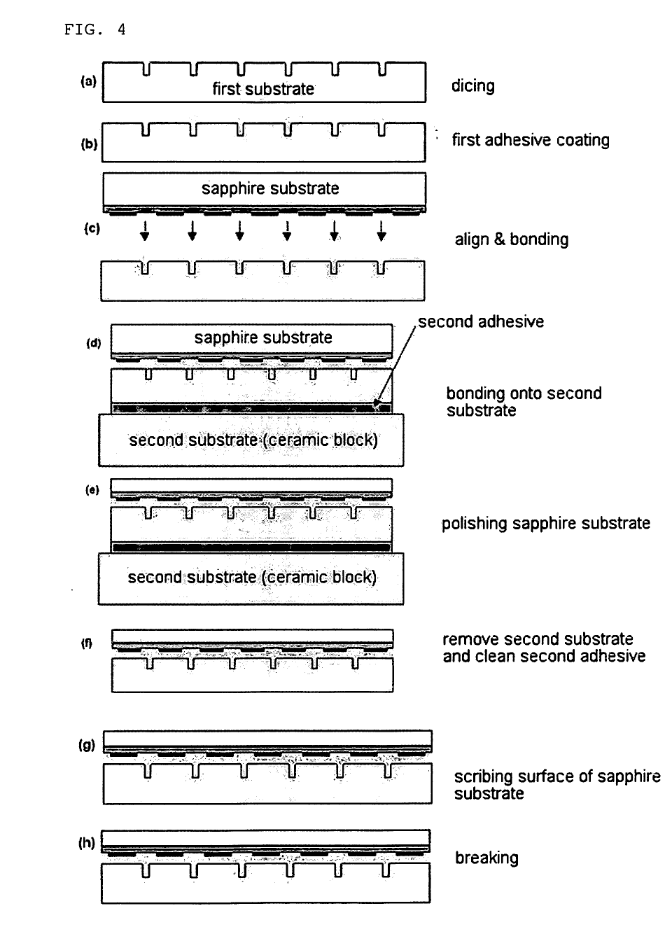

Hereinafter, the manufacturing process for the light emitting diode device according to the present invention, especially, the procedure for processing the sapphire substrate will be described in detail. FIG. 3 shows the method for polishing the sapphire substrate, and FIG. 4 shows the method for polishing the sapphire substrate employing the first substrate on which at least one recess is formed with a regular interval.

(1) Step of Growing a Light Emitting Diode Part on a Sapphire Substrate

A sapphire substrate (b) formed on one surface thereof with a light emitting part can be used without limitations. For instance, an n-type layer, an active layer (light emitting layer) and a p-type layer are sequentially grown from the sapphire substrate 10 through a metal organic chemical vapor deposition (MOCVD) process, etc.

The light emitting part grown from the sapphire substrate may include the n-type layer, the active layer and the p-type layer, which are made from GaN based compounds generally known in the art. For instance, a non-limitative example of the compounds includes GaN, GaAlN, InGaN, InAlGaN, or a mixture thereof. In addition, the active layer (light emitting layer) has a single quantum well structure or a multiple quantum well (MQW) structure. Besides the n-type layer, the active layer and the p-type layer, a buffer layer can be provided. It is possible to fabricate the light emitting diodes having various wavelengths from short wavelength to long wavelength by controlling components of the GaN compounds. As a result, not only a blue nitride-based light emitting diode having the wavelength of 460 nm, but also various light emitting diodes can be used.

At this time, the light emitting diodes can be continuously provided on the sapphire substrate, or at least one light emitting diode can be provided on the sapphire substrate with a regular interval.

(2) Etching Step

A predetermined region corresponding to the p-type layer and the active layer is dry etched to expose partially an upper surface of the n-type layer.

(3) Step of Forming the n-Type Ohmic Contact Layer

An n-type ohmic contact metal layer for applying a predetermined voltage therethrough is deposited on the n-type layer surface exposed in the etching step.

(4) Step of Forming the p-Type Ohmic Contact Metal Layer or Light Tranmissive p-Type Ohmic Contact Metal Layer

A light transmissive p-type ohmic contact metal layer is formed on an upper portion of the light emitting diode section, that is, the p-type layer surface. After heat treatment process is performed, then a p-type ohmic contact metal layer for wire bonding is formed. In this way, a p-type ohmic contact is formed. For more convenient fabrication, it is also possible to form the light transmissive p-type ohmic contact metal layer after the etching step (2), perform heat treatment and then simultaneously form the n-type ohmic contact metal layer and the p-type ohmic contact metal layer.

(5) Step of Bonding the First Substrate (See, FIG. 3b)

A first surface of the first substrate is bonded to the light emitting diode part (see, FIG. 3a) grown on the sapphire substrate by means of a first binder, thereby forming a bonded structure (see, FIG. 3b). Here, the bonded structure is called a “first bonded structure.”

The first substrate (a), which is an element of the bonded structure (first bonded structure), can fix the sapphire substrate through the light emitting diode part. In addition, if the unit chip can be formed through the scribing or breaking process in a state in which the sapphire substrate has been bonded to the first substrate, the size or thickness of the first substrate may not be specially limited. In order to improve productivity and to ensure mass production by facilitating the manufacturing process for the unit chip, the first substrate is preferably made from silicon or alumina, which can be easily split. In addition, preferably, the first substrate has a size and a shape identical to those of the sapphire substrate supported by the first substrate. Preferably, the first substrate has the size of 2 inches and the thickness of 150 to 300 μm. However, the present invention is not limited thereto. A non-limitative example of the first substrate includes a silicon wafer or an alumina ceramic wafer.

The first substrate is formed on at least one surface thereof with at least one recess aligned in a regular interval (see, FIG. 4a). The recess can be formed through the scribing and/or dicing process using a diamond tip or laser. The shape of the recess is not specially limited. For instance, the recesses can be aligned in a linear pattern, in which the recesses are parallel to each other, or in a cross stripe pattern, in which at least two linear lines cross each other. Preferably, but not exclusively, the position of the recess corresponds to a cutting line of the light emitting diode formed on the sapphire substrate.

If the recess is formed through the dicing process, the width of the recess is preferably set in a range of about 15 to 250 μm, and the depth of the recess is preferably set in a range of about 5 to 50% relative to the thickness of the first substrate. Meanwhile, it is difficult to adjust the width and the depth of the recess if the recess is formed through the scribing process. In this case, the width of the recess is preferably set in a range of about 1 to 100 μm, and the depth of the recess is preferably set in a range of about 1 to 50% relative to the thickness of the first substrate. For instance, when the recess is formed through the scribing process using the diamond tip, although it is difficult to precisely adjust the width and the depth of the recess to predetermined levels, the width and the depth of the recess can be adjusted to 2 μm and 1 to 10 μm, respectively. In addition, if the recess is formed through the scribing process using the laser, it is possible to cut the wafer by a half in a level of 50 μm or less. Although the width of the recess becomes enlarged in proportion to the laser power, it is also possible to adjust the width and the depth of the recess by controlling the laser power.

If the first substrate formed on at least one surface thereof with at least one recess aligned in a regular interval is employed, the first substrate can be easily separated into unit chips through the scribing or breaking process. Thus, a metal substrate, which is generally known in the art, can be used without limitations.

When the bonded structure (first bonded structure) is prepared by bonding the first substrate having at least one recess to the sapphire substrate having consecutive light emitting diodes, the first substrate formed on at least one surface thereof with at least one recess aligned in a regular interval is bonded to the light emitting diodes of the sapphire substrate by means of binders. At this time, if the sapphire substrate is formed with at least one light emitting diodes aligned in a regular interval, the light emitting diodes of the sapphire substrate are aligned in space sections formed between recesses provided on at least one surface of the sapphire substrate, and then bonded to the first substrate by means of binders (see, FIG. 4c).

A first binder used for bonding the sapphire substrate, on which the light emitting diodes are grown, to the first substrate includes an ordinary binder material generally known in the art, for instance, a polymer material which is in a solid phase at a normal temperature (for example, adhesive resin, UV curable resin, or thermoplastic resin). In a state in which the sapphire substrate has been bonded to the first substrate by means of the first binder, the first binder must allow the sapphire substrate to be polished for two hours under the temperature of about 70° C. The first bonded structure consisting of the sapphire substrate bonded to the first substrate by means of the first binder is shown in FIG. 3b.

(6) Step of Bonding the Second Substrate (See, FIG. 3c)

A second surface of the first substrate is bonded to a first surface of the second substrate by means of a second binder. Such a bonded structure is called a “second bonded structure.” The sectional shape of the second bonded structure is shown in FIG. 3c.

Since the second substrate is generally attached to lapping and polishing equipment in practice, the second substrate fixes the sapphire substrate while the sapphire substrate is being processed and then instantly removed when the sapphire substrate has been processed, so that the second substrate is not used in the following processes. Accordingly, the size of the second substrate may be appropriately determined according to the standard of the lapping and polishing equipment to be used, as possible. For instance, the second substrate has a thickness range of about 3 to 5 cm, and a non-limitative example of the second substrate includes a ceramic block.

A second binder used for bonding the bonded structure (first bonded structure) consisting of the sapphire substrate and the first substrate to the second substrate may include a polymer material, for example, adhesive resin, UV curable resin, or thermoplastic resin, which is in a solid phase at a normal temperature such that the sapphire can be processed in a state in which the second binder has been applied to the sapphire substrate.

At this time, the first and second binders used for bonding the first and second substrates according to the present invention must allow the sapphire substrate to be processed for two hours under the temperature of about 70° C. In addition, the first and second binders must have adhesive properties different from each other in such a manner that the sapphire substrate, the first substrate, and the second substrate can be sequentially separated from the second bonded structure. To this end, the first and second binders must have different adhesion-drop temperatures, melting points, selective solubility to solvent, and sensitivity to light radiation. In this case, the binders may not exert an influence upon the polished sapphire substrate while allowing the first and second substrates to be easily and sequentially removed from the final bonded structure, thereby simplifying the manufacturing process, improving productivity, and enhancing the performance of products.

In order to sequentially remove the first and second substrates from the bonded structures consisting of the first and second substrates and the sapphire substrate, the first and second binders must have adhesion-drop properties different from each other. In practice, the first and second binders are subject to adhesion-drop under different conditions. If the first and second binders are subject to the same condition, the adhesion force of the first binder is preferably greater than that of the second binder.

That is, if unique physical properties (e.g., melting point or selective solubility to solvents) of the second binder, which are distinctive from those of the first binder, are used for preferentially separating the second substrate from the final bonded structure consisting of the sapphire substrate, the first binder layer, the first substrate, the second binder layer and the second substrate as shown in FIG. 3c, only the second substrate can be easily separated while maintaining the bonding state between the sapphire substrate and the first substrate as it is. In addition, since the sapphire substrate can be fastened by means of the first substrate even after the second substrate has been separated from the second bonded structure, the structural stability of the sapphire substrate may not be degraded. Therefore, it is preferred for the first binder to have the physical properties different from those of the second binder. Although there are no specific limitations, the physical properties include the adhesion-drop temperature, melting point, selective solubility to solvent, and sensitivity to light radiation.

One of physical properties for distinguishing the first binder from the second binder is the adhesion-drop temperature, which refers to the temperature at which the adhesion force of a material is degraded before the state transition of the material occurs. Although there are no specific limitations for the adhesion-drop temperature range of the first and second binders, it is preferred to prevent the adhesion-drop from occurring at the normal temperature in order to allow the sapphire substrate to be easily processed. The differential adhesion-drop temperature (|T₁−T₂|) between the first and second binders T₁ and T₂ is preferably equal to or larger than 10° C. If the differential adhesion-drop temperature is less than 10° C., adhesion force of the first binder is also degraded when the second binder is peeled off, so that the first binder may be additionally peeled off. In this case, the temperature must be accurately controlled. In addition, since the sapphire substrate polishing process and the unit chip forming process are performed under the normal temperature, it is preferred for the first and second binders to have sufficient adhesion force at the normal temperature.

The first and second binders may include cool-peelable binders, adhesion force of which is degraded if the temperature drops below a predetermined level, or heat-peelable binders, adhesion force of which is degraded if the temperature rises above a predetermined level. When the first and second binders are cool-peelable binders, the adhesion-drop temperature (T₁) of the first binder is preferably set equal to or higher than the adhesion-drop temperature (T₂) of the second binder by 10° C. in such a manner that the second and first binders can be sequentially peeled off. In contrast, when the first and second binders are heat-peelable binders, the adhesion-drop temperature (T₁) of the first binder is preferably set equal to or lower than the adhesion-drop temperature (T₂) of the second binder by 10° C. If both the first and second binders are cool-peelable binders, the adhesion-drop temperature must be fallen by 20° C. or more from the normal temperature, so that not only a large-sized cooling apparatus is needed, but also water condensation may occur because the surface temperature is fallen. For this reason, the first and second binders are preferably prepared as heat-peelable binders.

Preferably, the first and second binders according to the present invention have melting points (primary transition temperature) different from each other. In order to allow the first and second binders to be sequentially separated (released), the melting point of the first binder is preferably higher than the melting point of the second binder, as possible. The melting point of the second binder is set to 40 to 120° C., preferably 70 to 120° C., and more preferably 80 to 100° C. In addition, the melting point of the first binder is set to 80 to 220° C., and preferably 120 to 140° C.

Non-limitative examples of the first and second binders include side chain crystalline polymer, pressure sensitive adhesive, thermal foaming agent, heat foaming adhesive, plasticizer having the high boiling point, organic crystal, and mixtures thereof. In particular, it is preferred for the first and second binders to have the melting points (primary transition temperature) within a narrow temperature range less than a temperature range of 15° C.

The side chain crystalline polymer includes a side chain crystalline repeat unit induced from acrylate or methacrylate ester, and side chain non-crystalline repeat unit induced from acrylate or methacrylate ester. That is, in —COOR₁ of the side chain crystalline repeat unit, R₁ is an alkyl radical having at least 14 carbon atoms. In addition, in —COOR₂ of the side chain non-crystalline repeat unit, R₂ is a linear-chain or a branch-chain alkyl radical having at least one carbon atom. Crystallizable monomers include: fluoroacrylate, methacrylate and acrylate corresponding to vinyl ester polymer; substituted acrylamide and maleimide polymers; polyalkyl vinyl ether; polyalkylethylene oxide; polyisocyanate; polyurethane obtained from the reaction of an amine-containing monomer or an alcohol-containing monomer with alkyl isocyanate, polyester or polyether; polysiloxane and polysilane; alkylstyrene polymer, or the like. The melting point range of about 20 to 100° C. can be changed depending on the type of side chain in side chain crystalline polymer and the number of crystalline units. At this time, the melting point range can be narrowed within a temperature range of about 15° C., preferably less than a temperature range of about 5° C. Therefore, if the temperature is slightly changed by a predetermined level, reversible reaction may occur between a crystal part and a non-crystal part of side chain crystalline polymer while suddenly dropping adhesion force of the binders, so that the substrates can be easily released from the binders.

Adhesives generally known in the art may serve as the pressure sensitive adhesive. The pressure sensitive adhesive includes polymer, a polymer mixture, or a polymer composition containing plasticizer, tackifier, filler, stabilizer, defoaming agent, antistatic agent or the like. Non-limitative examples of the adhesive formed of a silicone composition include a linear or three-dimensional polyorganosiloxane comprising R₂SiO units (D units) or R₃SiO0.5 units (M units) and SiO₂ units (Q units) (wherein R is a C1-C10 linear or cyclic alkyl group), epoxy-containing polyorganosiloxane, polyorgarnosiloxane end-capped with an epoxy group, or the like.

A thermosetting compound forms a three-dimensional basic net structure over the whole area of the adhesive according to thermal polymerization initiator, which is subject to heat-treatment under the temperature range of about 50 to 150° C., thereby degrading the adhesion force of the adhesive. Accordingly, the heat curable adhesive (pressure sensitive adhesive+monomer or oligomer+initiator) preferably includes low-molecular weight compounds or oligomer having at least two photo-induced polymeric C—C double bonds in a molecule which can be formed in a three-dimensional net structure. For instance, the heat curable adhesive includes acrylate-based compounds, or urethane acrylate-based oligomer.

The thermal foaming adhesive includes a heat-peelable adhesive composition and an acryl-based adhesive. The heat-peelable adhesive composition includes polymer obtaining by copolymerizing vinylbutyral radical (unit repeat: 3˜600), vinylacetate radical (unit repeat: 1˜80), and vinylalcohol radical (unit repeat: 4˜700). The heat-peelable adhesive composition may further include an acryl based adhesive.

The organic crystal refers to an organic substance which can maintain a crystal phase at the temperature less than a melting point thereof. Crystal is maintained with a crystalline state in the operational temperature range of the adhesive, and the adhesive force can be improved if wettability relative to the substrate is enhanced by reducing gel contents in the adhesive. In addition, if the temperature reaches the melting point of the organic crystal beyond the operation temperature range, the organic crystal is dissolved and shifted into an interfacial surface between the substrate and the adhesive, so that the adhesive force between the substrate and the adhesive is significantly reduced, allowing the substrate to be easily released from the adhesive. Organic crystal generally known in the art can be used without specific limitations.

The thermal foaming agent includes a thermally expandable microsphere, which is obtained by encapsulating a material such as isobutane, propane, or pentane, which can be easily evaporated, by using at least one selected from the group consisting of vinylidenechlorite-acrylonitrile copolymer, polyvinyl alcohol, polyvinylbutyral, polymethylmethacrylate, polyacrylonitrile, polyvinylidenechlorite and polystyrene. The thermally expandable microsphere has a size of about 1 to 100 μm. However, the present invention is not limited thereto.

If the thermal foaming agent is added to the adhesive, gas is emitted when the heating temperature reaches the foaming temperature of the thermal foaming agent beyond the operational temperature range of the adhesive. At this time, a volume of the adhesive may increase so that coherence and a contact area between the substrate and the adhesive may be reduced, allowing the adhesive to be easily released from the substrate. The components of the thermal foaming agent may not be specifically limited so long as the initial foaming temperature of the thermal foaming agent, at which gas is emitted, is higher than the operational temperature of a product provided with the adhesive. If the initial foaming temperature is too low, the adhesive may be easily peeled off. In contrast, if the initial foaming temperature is too high, a heating temperature required for peeling off the adhesive may excessively rise, causing bad influence upon other components. Non-limitative examples of the thermal foaming agents include inorganic foaming agent, organic foaming agent or mixtures thereof, which are generally known in the art. When plasticizer having a high boiling point is employed, bonding property (coherence) between the adhesive and the substrate can be improved during the manufacturing process. If the plasticizer has a boiling point exceeding 150° C., the plasticizer may be evaporated in the adhesive, thereby degrading the adhesion force between the adhesive and the substrate. However, if plasticizer having a boiling point less than 150° C. is employed, problems may occur in terms of heat-resistant property. In addition, the plasticizer may be evaporated when it has been used for a long period of time and contaminate other components, so the plasticizer having a boiling point less than 150° C. is not preferable in the present invention.

The first and second binders according to the present invention can be released through light radiation without applying heat to the first and second binders. Accordingly, an UV curable adhesive, adhesion force of which is degraded as light, such as UV light, is irradiated thereon, can be used for the first and second binders. At this time, the first and second substrates incorporating with the first and second binders must allow UV light to pass therethrough, and the first and second binders are preferably made from materials having sensitivity to light radiation corresponding to light permeability of the first or second substrate. In particular, if an UV permeable substrate is used as the second substrate, an UV curable adhesive, which is additionally cured upon light radiation so that the adhesion force thereof is significantly reduced, can be used for the second binder. Meanwhile, a typical adhesive can be used for the first binder regardless of the temperature range thereof. Preferably, a heat-peelable adhesive is used as the first binder.

The bonding steps for the first and second substrates can be performed by utilizing the above-mentioned bonded structures while applying heat and/or pressure thereto. At this time, there are no specific limitations to the temperature range applied to the first and second substrates so long as the temperature is equal to or higher than the adhesion-drop temperature or the melting point of the adhesive. In addition, there are no specific limitations to the pressure range applied to the first and second substrates. For instance, heat is applied to melt the binders during the bonding steps, and then the temperature is again fallen.

7) Step of Processing (Polishing) the Substrate Surface of the Sapphire Substrate

In the resultant final bonded structure from step 6), the second surface of the sapphire substrate is polished. For example, the second surface of the sapphire substrate is subjected to grinding, lapping and polishing processing. At this time, the grinding process serves to rapidly grind the sapphire substrate to a target thickness, and the subsequent lapping and polishing processes serve to perform mirror finishing for the ground surface. The reason why the back side of the sapphire substrate is subjected to the mirror finishing is that a frontal pattern of the light emitting diode section must be identified through the back side of the sapphire substrate during the subsequent scribing/breaking process.

Whereas the second substrate fastens the sapphire substrate until the grinding, lapping and polishing processes for thinning the sapphire substrate as in the prior art, the first substrate exists in a state where it is bonded onto the sapphire substrate until the unit chips are formed and then bonded onto the lead frame, so the sapphire substrate can be processed to a thickness less than the conventional thickness limit, that is, 80 μm, preferably between 5 and 80 μm, more preferably less than 40 μm. In this way, the present invention provides a sapphire substrate having a smaller thickness than that of the conventional sapphire substrate, thereby making it possible to enhance the heat dissipation efficiency of the light emitting diode device.

8) Step of Removing the Second Substrate (See, FIG. 3e)

The unique physical properties of the second binder, such as the adhesion-drop temperature, the melting point, sensitivity to light radiation and selective solubility to solvents, are utilized so as to easily remove the second substrate from the bonded structure (second bonded structure) consisting of the sapphire substrate, the first substrate and the second substrate. Thus, the second bonded structure has a configuration identical to that of the first bonded structure (see, FIG. 3e).

That is, the second substrate is separated from the second bonded structure based on the unique physical properties of the second binder, which are distinctive from those of the first substrate. For example, the second substrate can be removed through the steps of 1) heating or cooling the first and second binders with a temperature higher or lower than the adhesion-drop temperature of the first and second binders; 2) selectively radiating light onto the first binder or the second binder; and 3) applying a solvent capable of selectively dissolving the first binder or the second binder, or 4) utilizing at least one of steps 1) to 3). Preferably, the second substrate is removed by heating the second binder with a temperature higher than the adhesion-drop temperature of the second binder and lower than the adhesion-drop temperature of the first binder, or by cooling the second binder with a temperature lower than the adhesion-drop temperature of the second binder and higher than the adhesion-drop temperature of the first binder.

As an example, when the second substrate is removed, heat is applied to the bonded structure to separate the second substrate from the bonded structure and then the temperature is fallen. At this time, residual binder material adhering to the surface is dissolve out using an organic solvent such as alcohol, acetone or the like. Even after the second substrate is separated, the sapphire substrate is fixed as it is by means of the first substrate.

9) Step of Separating Unit Chips (See, FIG. 3f)

The bonded structure consisting of the first substrate and the sapphire substrate processed to have the thickness of about 5 to 80 μm is subject to the scribing/breaking process so as to form unit chips.

Typical methods generally known in the art, such as dicing, scribing and breaking processes, can be performed in order to separate the unit chips. In addition, it is also possible to irradiate laser beam so as to separate the unit chips. For example, the unit chips can be separated from the bonded structure by performing the breaking process only. In addition, the unit chips can be separated from the bonded structure by performing the scribing process with respect to the sapphire substrate which has been mirror-polished, and then performing the breaking process with respect to the first substrate after selectively dicing or scribing the first substrate. In particular, if the first substrate is formed with recesses aligned in a regular interval through the dicing or scribing process in such a manner that the bonded structure is positioned corresponding to a breaking position, the unit chips can be easily separated from the first substrate by simply performing the breaking process relative to the recess part of the first substrate, or performing the breaking process after scribing the first substrate (see, FIGS. 4g and 4h).

In general, if the sapphire substrate is processed to have the thickness of 80 μm or less, crack may be created vertically to the recesses scribed on the surface of the adhesive upon a typical scribing process, so that the unit chips can be easily separated from the first substrate. Accordingly, the breaking process is performed along the recess part of the first substrate having recesses aligned in a regular interval. In addition, laser can be irradiated onto the sapphire substrate in order to separate the unit chips. That is, the unit chips can be obtained from the sapphire substrate by using laser only. In addition, the breaking process can be performed in a state in which the sapphire substrate is scribed by a depth of about 10 to 20 μm by means of laser. In this case, the unit chips are simultaneously separated from the sapphire substrate and the first substrate.

In general, the scribing refers to an operation of drawing lines on a wafer surface by a diamond tip which has a pointed end and a strength of which is excellent, and the breaking refers to an operation of cutting off the wafer by impacting the wafer along the lines drawn during the scribing.

10) Step of Bonding the Unit Chip to the Lead Frame and Separating First Substrate

The second surface of the polished sapphire substrate is bonded onto the lead frame for packaging the light emitting diodes, and then the first substrate is separated based on the unique physical property of the first binder.

Easy-to-bond materials well-known in the art may be used for bonding the sapphire substrate onto the lead frame, and a non-limitative example of the east-to-bond materials includes silver paste, solder and so firth. In addition, if it is necessary to enhance adhesion force between the second surface of the sapphire substrate and the lead frame, a metal thin layer can be deposited on the surface of the sapphire substrate. At this time, In-based alloy or Sn-based alloy having a low melting point, such as AgSn or AuSn, can be deposited on the surface of the sapphire substrate as a bonding metal. Preferably, the metal thin layer is deposited prior to the step of separating the unit chip from the polished sapphire substrate and the first substrate.

Similar to the step of removing the second substrate described in step (8), the first substrate can be easily removed from the bonded structure (first bonded structure) consisting of the first substrate and the sapphire substrate attached to the lead frame.

11) Wire Bonding Step

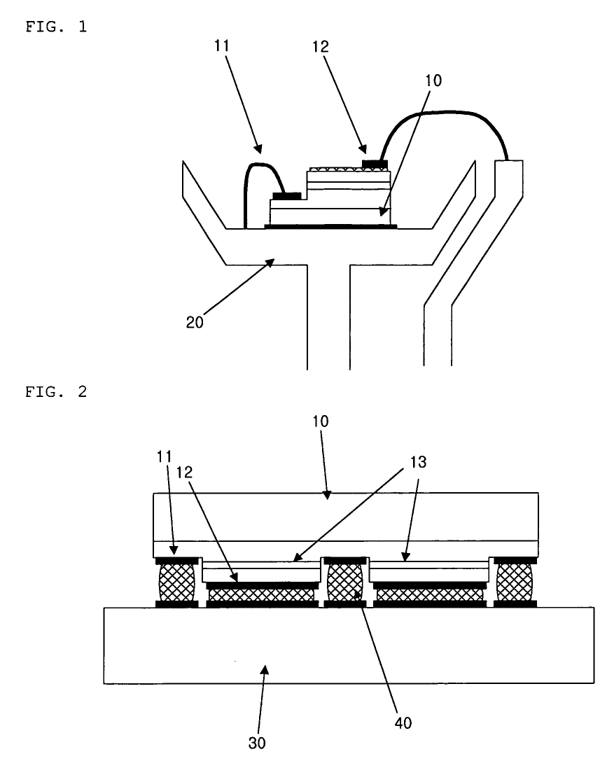

Next, the n-type ohmic contact metal layer and the p-type ohmic contact metal layer of the light emitting diode section grown on the sapphire substrate are connected to an external power source through gold wire bonding, respectively. In this way, a top emission-type light emitting diode device as shown in FIG. 1 is fabricated. The lead frame shown in FIG. 1 is a lamp-type lead frame which is mainly used for fabricating a low-output light emitting diode device, and a surface mount device (SMD)-type lead frame is used in a high-output light emitting diode device.

12) Molding Step

Subsequently, the light emitting diode section is covered with a molding material such as epoxy, a fluorescent substance or a molding material mixed with a fluorescent substance, by which the fabrication of the light emitting diode device is completed.

The light emitting diode device having the above-mentioned structure may be operated according to the following principle. That is, if a specific voltage is applied through a wire connected to the external power source, a cathode of the light emitting diode device is connected to the external power source through the n-type electrically conductive pad section, the n-type ohmic contact metal layer and the n-type layer, and an anode of the light emitting diode device is connected to the external power source through the p-type electrically conductive pad section, the p-type ohmic contact metal layer and the p-type layer, so an electric current flows through the light emitting diode device. By this, light with energy corresponding to a band gap or an energy level difference of the active layer is emitted while electrons and holes are recombined with each other in the active layer.

The fabricating method of a light emitting diode device as stated above is only one of many preferred embodiments, and the present invention is not limited to this.

If the above-proposed technology for processing a sapphire substrate is employed, it is possible to fabricate a top emission-type light emitting diode device having advantages of a simple fabrication process, low unit cost of production and high mass production capability and so forth. Especially, since such a light emitting diode device has an improved heat dissipation efficiency and thus its reliability is secured, it can have an advantage over other light emitting diode devices in manufacturing applications, such as a light source for LCD TV, an illuminator and the like, which are expected to form a vast market in the future. The sapphire substrate processing technology according to the present invention may become an echo-making turning point in the manufacture of high-output light emitting diodes.

The present invention also provides a light emitting diode device fabricated by the above-mentioned fabricating method or including the above-mentioned bonded structure and/or the unit chip. At this time, the above light emitting diode device may include typical light emitting diode devices generally known in the art without incurring specific limitations in relation to the manufacturing methods, output schemes, and wavelength ranges of light. The present invention is applicable for all kinds of light emitting diode devices including the sapphire substrate as an element thereof.

In addition, the present invention provides a light emitting unit with a light emitting diode device which is fabricated by the above-mentioned method. The light emitting unit includes all kind of light emitting unit having a light emitting diode device, for example, a lighting apparatus, an indicator unit, a sterilizer lamp, a display unit and so forth.

Additional advantages, objects, and features of the invention will be set forth in part in the description which follows and in part will become apparent to those having ordinary skill in the art upon examination of the following or may be learned by practicing the invention. The objectives and other advantages of the invention may be realized and attained by the structure particularly pointed out in the written description and claims hereof as well as the appended drawings.

### BEST MODE FOR CARRYING OUT THE INVENTION

Reference will now be made in detail to the preferred embodiments of the present invention. It is to be understood that the following examples are illustrative only and the present invention is not limited thereto.

### Embodiment 1

1-1. Bonding Sapphire Substrate to Silicon Wafer

Using PMMA as a first binder, a 2-inch sapphire substrate, on which a GaN-based light emitting diode section had been grown, was bonded onto a 2-inch silicon wafer with a thickness of 250 μm. At this time, the PMMA was dissolved in a concentration of about 30% in dichloroethane and then spin-coated on the top of the silicon wafer. The coated silicon wafer was dried at 110° C. for 10 minutes, and a surface of the silicon wafer, on which the PMMA has been coated, was pressed against a light emitting diode section surface of the sapphire substrate at 180° C. by means of a press. In this way, the sapphire substrate and the silicon wafer were bonded onto each other.

1-2. Bonding Ceramic Block to Fist Bonded Structure Consisting of Sapphire Substrate and Silicon Wafer

Subsequently, a ceramic block was heated to 125° C., and shift wax was put on a ceramic block portion to be bonded. The shift wax was a product which is generally used for adhering the ceramic block onto the sapphire substrate in the sapphire substrate processing according to the prior art, and is in a solid phase at a normal temperature, but converted into a liquid phase at about 125° C. The back side of the silicon wafer with the bonded sapphire substrate was bonded onto the molten shift wax and then cooled down to a normal temperature while being pressed by means of a press, through which the bonding work was completed.

1-3. Polishing Second Surface (Back Side) of Sapphire Substrate

The back side of the sapphire substrate was ground using a diamond pallet plate and then was subjected to lapping and polishing processing to process the sapphire substrate to a thickness of 35 μm.

1-4. Removal of Ceramic Block

In order to remove the ceramic block, the ceramic block was heated again to 125° C. to melt the shift wax and separate the bonded structure of the sapphire substrate and the silicon wafer from the ceramic block. Residual shift wax was washed out using alcohol. At this time, the PMMA, by which the silicon wafer and the sapphire wafer had been bonded onto each other, remained unreacted.

1-5. Forming Unit Light Emitting Diode Chip and Bonding to Lead Frame

Next, the sapphire substrate surface was subjected to scribing and breaking processing to dice the sapphire substrate into unit light emitting diode chips. The sapphire substrate surface of the diced unit light emitting diode chip was bonded onto a lead frame at about 130° C. by means of silver paste.

1-6. Silicon Wafer Removal and Light Emitting Diode Device Fabrication

Thereafter, the PMMA was dissolved out by dipping the lead frame into acetone. At the same time, the silicon wafer was removed and the light emitting diode structure was washed through additional acetone treatment. Gold wire bonding and molding were carried out for the exposed light emitting diode structure to complete the fabrication of the light emitting diode device.

As described above, the present invention provides a method for minimizing the thickness of a sapphire substrate which is used for the fabrication of a top emission-type light emitting diode device. The method of the present invention can significantly improve heat dissipation as compared with a top emission-type structure of the prior art, so it can be usefully applied to the fabrication of high-output light emitting diodes.

### Embodiment 2

Embodiment 2 is substantially identical to above-described Embodiment 1, except that a silicon wafer formed with recesses aligned in a regular interval is used as the first substrate to be bonded to the sapphire substrate, and dicing lines of the silicon wafer and the sapphire substrate are aligned corresponding to cutting lines of the unit chips when the silicon wafer is bonded to the sapphire substrate. The procedure for forming the recesses on the silicon wafer is described below in detail.

A dicing process has been performed with respect to a front surface of a 2-inch silicon wafer by using dicing equipment in such a manner that dicing lines are formed on the silicon wafer with a depth corresponding to 26% of the silicon wafer thickness. Since the thickness of the silicon wafer is about 380 μm, the dicing lines have the thickness of about 100 μM and the width of about 50 μm, which corresponds to the width of the dicing blade. The dicing period on the silicon wafer is 1 mm. After dicing the silicon wafer in one direction, the dicing process is again performed over the whole area of the silicon wafer by rotating the silicon wafer at an angle of 90°, thereby allowing the silicon wafer to have the chip size (1×1 mm²) of the light emitting diode.

### Embodiment 3

Using wax as a first binder, a 2-inch sapphire substrate formed with a GaN-type light emitting diode section has been bonded onto a 2-inch silicon wafer having a thickness of about 250 μm. At this time, the shift wax is placed on a bonding section and is heated under the temperature of about 120° C., in such a manner that the silicon wafer can be bonded with the light emitting diode section of the sapphire substrate by means of a liquid-phase shift wax. Then, the resultant structure is pressed under the temperature of about 120° C. by means of a press unit. After that, a second binder including side chain crystalline polymer and the pressure sensitive adhesive is attached to the ceramic block by rising the temperature of the ceramic block to a level of 70 to 100° C. Then, after primarily polishing the second surface (rear surface) of the sapphire substrate by using a diamond plate and water, the second surface of the sapphire substrate is secondarily polished by using oil containing CMP slurry. Then, the second surface of the sapphire substrate is gradually polished by using oil containing CMP slurry, thereby thinning the thickness of the sapphire substrate to a level of 35 μm. After that, the ceramic block is again heated under the temperature of about 70 to 100° C., in such a manner that the ceramic block can be removed from the bonded structure consisting of the sapphire substrate and the silicon wafer. Then, the unit chip separated from the bonded structure is attached to the lead frame. At this time, the bonding temperature is controlled to a level of 100° C., in order to prevent the first binder (wax) from being peeled off. Thereafter, IPA is applied to the lead frame so as to melt the wax and remove the silicon wafer, and then a cleaning process has been performed by additionally providing IPA. Then, an Au wire bonding and a molding process are performed with respect to the exposed structure of the light emitting diode device, thereby obtaining the light emitting diode device according to the present invention.

### Embodiments 4˜13

The light emitting diode device was fabricated through the procedure identical to that of Embodiment 1, except that the first and second binders as shown in Table 1 had been used.

TABLE 1

| Ex | First binder | Second binder |
|---|---|---|
| 4 | Wax; heated with 120° C. for | Thermally curable adhesive; |
| | bonding work; released while | cured when it is heated between |
| | being dissolved by IPA at 120° C. | 70 and 120° C., lowering adhesion force |
| 5 | The same as Embodiment 4 | Thermal foaming agent; added to adhesive |
| | | and foamed when it is heated between 70 and |
| | | 100° C., facilitating release of adhesive |
| 6 | Thermally curable adhesive; | Side chain crystalline polymer + pressure |
| | provided with pressure | sensitive adhesive; |
| | sensitive adhesive agent + thermally | released when it is heated |
| | curable compound, | between 70 and 100° C. |
| | cured when it is heated between | |
| | 100 and 150° C., lowering | |
| | adhesion force | |
| 7 | Thermal foaming agent; added in | Thermal foaming agent; added in |
| | adhesive with initial foaming | adhesive with initial foaming |
| | temperature of 100 to 200° C., | temperature of 70 to 120° C., |
| | foamed by heat to facilitate | foamed by heat to facilitate |
| | release of adhesive; initial | release of adhesive; initial |
| | foaming temperature is higher | foaming temperature is higher |
| | than operational temperature of | than operational temperature of |
| | adhesive by 10° C. | adhesive by 10° C. |
| 8 | The same as Embodiment 7 | Side chain crystalline polymer + pressure |
| | | sensitive adhesive; |
| | | released when it is heated |
| | | between 70 and 100° C. |
| 9 | The same as Embodiment 7 | Thermal foaming adhesive; |
| | | foamed or thermally expanded |
| | | when it is heated between 100 |
| | | and 120° C., facilitating release |
| | | of adhesive |
| 10 | Thermal foaming adhesive; | Side chain crystalline polymer + pressure |
| | foamed or thermally expanded | sensitive adhesive; |
| | when it is heated between 100 | released when it is heated |
| | and 120° C., facilitating release | between 70 and 100° C. |
| | of adhesive | |
| 11 | Binder with plasticizer having | Side chain crystalline polymer + pressure |
| | high boiling point; provided | sensitive adhesive; |
| | with plasticizer having boiling | released when it is heated |
| | point above 150° C., adhesion | between 70 and 100° C. |
| | force is reduced when | |
| | temperature exceeds 150° C., | |
| | facilitating release of | |
| | adhesive | |
| 12 | The same as Embodiment 11 | Thermal foaming agent; added in |
| | | adhesive with initial foaming |
| | | temperature of 70 to 120° C., |
| | | foamed by heat to facilitate |
| | | release of adhesive |
| 13 | Binder with organic crystal; | Binder with organic crystal; |
| | using organic crystal having | using organic crystal having |
| | melting point of 120 to 150° C., | melting point of 70 to 120° C., |
| | thereby reducing adhesion force | thereby reducing adhesion force |
| | by applying heat above 120° C. | by applying heat of 70 to 120° C. |

The light emitting diode devices provided with the above first and second binders were normally operated and the heat dissipation efficiency thereof is enhanced by about 50%.

### INDUSTRIAL APPLICABILITY

As described above, the present invention provides a method for minimizing the thickness of a sapphire substrate which is used for the fabrication of a top emission-type light emitting diode device. The method of the present invention can significantly improve heat dissipation as compared with a top emission-type structure of the prior art, so it can be usefully applied to the fabrication of high-output light emitting diodes.

While this invention has been described in connection with what is presently considered to be the most practical and preferred embodiment, it is to be understood that the invention is not limited to the disclosed embodiment and the drawings. On the contrary, it is intended to cover various modifications and variations within the spirit and scope of the appended claims.

1. A method for fabricating a light emitting diode device which has a light emitting diode section grown on a sapphire substrate, the method comprising the steps of:
(a) bonding the light emitting diode section grown on a first surface of the sapphire substrate to a first surface of a first substrate by means of a first binder;
(b) bonding a second surface of the first substrate to a first surface of a second substrate by means of a second binder;
(c) removing the second substrate from a bonded structure obtained as a result of step (b) after polishing a second surface of the sapphire substrate;
(d) separating the bonded structure into unit chips after the second substrate has been removed from the bonded structure; and
(e) bonding the second surface of the polished sapphire substrate provided in each unit chip to a lead frame, and then removing the first substrate.

2. The method as claimed in claim 1, wherein the first substrate is made of material which can be processed by scribing/breaking process.

3. The method as claimed in claim 1, wherein the first substrate is formed on at least one surface thereof with at least one recess aligned in a regular interval.

4. The method as claimed in claim 1, wherein the first binder used in step (a) has an adhesion-drop temperature different from that of the second binder used in step (b), and a differential adhesion-drop temperature between the first and second binders is equal to or larger than 10° C.

5. The method as claimed in claim 1, wherein the first binder in step (a) has melting point different from that of the second binder in step (b), and the first binder has a higher melting point than that of the second binder.

6. The method as claimed in claim 1, wherein the first and second binders are made from materials having sensitive to light radiation corresponding to light permeability of the first substrate or the second substrate.

7. The method of claimed in claim 1, wherein the first in step (a) and the second binder in step (b) are soluble to different solvents from each other.

8. The method as claimed in claim 1, wherein the first and second binders include at least one selected from the group consisting of side chain crystalline polymer, pressure sensitive adhesive, thermal foaming agent, heat foaming adhesive, plasticizer having a high boiling point, and organic crystal.

9. The method as claimed in claim 1, wherein the bonding in steps (a) and (b) is performed by applying heat, pressure or both of them simultaneously.

10. The method as claimed in claim 1, wherein, in steps (c) and (e), the first and second substrates are removed through the sub-steps of:
1) heating (or cooling) the first and second binders with a temperature higher (or lower) than an adhesion-drop temperature of the first and second binders;
2) selectively radiating light onto the first binder or the second binder; and
3) applying a solvent capable of selectively dissolving the first binder or the second binder, or
4) utilizing at least one of sub-steps 1) to 3).

11. The method as claimed in claim 10, wherein, in step (c), the second substrate is removed by heating the second binder with a temperature higher than the adhesion-drop temperature of the second binder and lower than the adhesion-drop temperature of the first binder, or by cooling the second binder with a temperature lower than the adhesion-drop temperature of the second binder and higher than the adhesion-drop temperature of the first binder.

12. The method as claimed in claim 1, wherein the thickness of sapphire substrate polished in step (c) is in a range of 5 to 80 μm.

13. The method as claimed in claim 1, wherein, in step (d), the unit chip is obtained by:
(a) performing a scribing process or a breaking process with respect to the bonded structure consisting of the sapphire substrate and the first substrate;
(b) irradiating laser onto the bonded structure consisting of the sapphire substrate and the first substrate; or
(c) performing the breaking process with respect to the bonded structure after separating a part of the bonded structure consisting of the sapphire substrate and the first substrate by using laser irradiation;

14. The method as claimed in claim 1, prior to step (a), further comprising the steps of:
(i) etching the light emitting diode section grown on the sapphire substrate to expose an n-type layer and then depositing an n-type ohmic contact metal layer on the exposed n-type layer; and
(ii) depositing a p-type ohmic contact metal layer on a p-type layer of the light emitting diode section grown on the sapphire substrate; or
following step (e), further comprising the step of wire bonding, molding treatment or wire bonding and molding treatment for a light emitting diode section surface which is exposed as the first substrate is separated.

15. A light emitting diode device fabricated by the method as claimed in claim 1.

16. A bonded structure comprising:
(a) a first substrate made from a material suitable for a breaking process; and
(b) a sapphire substrate formed on a first surface thereof with a light emitting diode section, wherein a first surface of the first substrate is bonded to the light emitting diode section of the sapphire substrate by means of a binder.

17. A bonded structure comprising:
(a) a first substrate formed on at least one surface thereof with at least one recess aligned in a regular interval; and
(b) a sapphire substrate formed on a first surface thereof with a light emitting diode section, wherein a first surface of the first substrate is bonded to the light emitting diode section of the sapphire substrate by means of a binder.

18. The bonded structure as claimed in claim 16 or 17, wherein the first substrate has the same size or larger than that of the sapphire substrate.

19. The bonded structure as claimed in claim 16 or 17, wherein the first substrate is metal substrate, silicon wafer or ceramic wafer.

20. The bonded structure as claimed in claim 17, wherein light emitting diode sections aligned on the sapphire substrate with a regular interval are fixedly positioned in spaces formed between the recesses aligned on at least one surface of the first substrate by means of adhesives.

21. The bonded structure as claimed in claim 17, wherein the recess is formed through a scribing process or a dicing process.

22. The bonded structure as claimed in claim 17, wherein the recesses are aligned in a linear pattern, in which the recesses are parallel to each other, or in a cross stripe pattern, in which at least two linear lines cross each other.

23. The bonded structure as claimed in claim 16 or 17, wherein the sapphire substrate has a thickness in a range of about 150 to 700 μm before the sapphire substrate is polished, and has a thickness in a range of about 5 to 80 μm after the sapphire substrate has been polished.

24. A unit chip obtained by separating a bonded structure consisting of a first substrate and a sapphire substrate after polishing the sapphire substrate such that the sapphire substrate has a thickness in a range of about 5 to 80 μm.
